(19) United States
(12) Patent Application Publication
(10) Pub. No.: US 2006/0035429 A1
(43) Pub. Date: Feb. 16, 2006

(54) Methods of forming phase-change random access memories including a confined contact hole and integrated circuit devices including the same

(76) Inventor: Byeong-Ok Cho, Seoul (KR)

Correspondence Address: MYERS BIGEL SIBLEY & SAJOVEC, PO BOX 37428, RALEIGH, NC, 27627, US

(21) Appl. No.: 11/188,826

(22) Filed: Jul. 25, 2005

(30) Foreign Application Priority Data
Aug. 11, 2004 (KR) 2004-0063301

(51) Int. Cl. H01L 21/8239

(52) U.S. Cl. 438/238; 438/95; 438/381

(57) ABSTRACT

Methods of forming a phase-change random access memory (PRAM) include forming a lower electrode layer and a node insulating layer on an active region of a semiconductor substrate. A photoresist pattern is formed on the node insulating layer that includes an opening therein. A polymer layer is formed on the photoresist pattern and the node insulating layer. The polymer layer is etched using the photoresist pattern as an etching mask to expose the node insulating layer while leaving a portion of the polymer layer after etching on a top surface of the exposed node insulating layer and on a sidewall of the opening of the photoresist pattern. The node insulating layer is etched using the photoresist pattern and the polymer layer as an etching mask to form a confined contact hole extending through the node insulating layer to contact the lower electrode layer while forming a polymer layer on a sidewall of the confined contact hole as a byproduct of etching the node insulating layer. The photoresist pattern, the portion of the polymer layer and the polymer layer on the sidewall of the confined contact hole are removed from the semiconductor substrate and a phase-change layer is formed on the node insulating layer to substantially fill the confined contact hole.

### CROSS-REFERENCE TO RELATED APPLICATION

This patent application is related to and claims priority from Korean Patent Application No. 10-2004-0063301, filed Aug. 11, 2004, the contents of which are hereby incorporated by reference in their entirety.

### BACKGROUND OF THE INVENTION

The invention relates to integrated circuit memory devices and, more particularly, to phase-change random access memories and methods of forming the same.

A phase-change random access memory (PRAM) typically includes a transistor and a phase-change layer pattern. The PRAM further generally includes a plurality of contacts for electrically connecting the phase-change layer pattern to the transistor. One of the contacts may expose a source region or a drain region of the transistor, and remaining ones of the contacts are generally disposed above the one contact to overlap the phase-change layer pattern. The PRAM typically can phase-change a crystalline structure of the phase-change layer pattern by using current flowing through the transistor and the contacts. As such, the PRAM may store data having a “0” or “1” value in a selected cell by using the crystalline structure of the phase-change layer pattern. As such, techniques of reducing a diameter of the contact, which is disposed under the phase-change layer pattern, have been applied to the PRAM in order to reduce a current/power consumption required for phase-changing the crystalline structure of the phase-change layer pattern.

The contact under the phase-change layer pattern may be difficult to implement on a semiconductor substrate as device density increases due to the shrinkage of a design rule for an increased density PRAM device. In particular, a photolithography process used to define a contact image on a photoresist layer in manufacturing the PRAM device may be limited in its ability to meet the design rule for the increased density device. Furthermore, the performance limit of the photolithography process may affect a subsequent etching process so that additional semiconductor fabrication processes may not be performed on the semiconductor substrate in a manner that would satisfy the design rule. If the more stringent design rule must be satisfied to meet demands of the semiconductor device market, the contact under the phase-change layer pattern may need to overcome the limitations of the photolithography process so as to be properly implemented on the semiconductor substrate.

U.S. Patent Publication No. 2002/0197566 to Maimom et al. (the '566 publication) describes a method of making a programmable resistance memory element. As described in the '566 publication, the method includes providing a first material layer, which may be a conductive layer. A second material layer is formed on the first material layer. The second material layer is described as a photoresist layer. The second material layer is partially removed to form a photomask on the first material layer. The photomask is described as being silylated and a silylation layer is formed on a top surface and a sidewall of the photomask. The silylation layer may be formed by diffusing silicon atoms into the photoresist layer.

The method described in the '566 publication further includes forming a third material layer on the first material layer and the silylation layer. The third material layer is a photoresist layer. The third material layer is partially removed. The silylation layers on the side and top surface of the photomask are then removed. The first material layer is partially removed by using the first material layer and the photomask as an etching mask to form an opening. A programmable resistance material is deposited in the opening.

The method described in the '566 publication uses photolithography processes twice while the opening is being formed. This approach may cause an increase in the production cost of the semiconductor device. Furthermore, if the third material layer and the silylation layer cannot be partially removed in-situ using a single apparatus, the method may further increase the production cost of the semiconductor device.

### SUMMARY OF THE INVENTION

Embodiments of the present invention include methods of forming a phase-change random access memory (PRAM), including forming a lower electrode layer and a node insulating layer on an active region of a semiconductor substrate. A photoresist pattern is formed on the node insulating layer that includes an opening therein. A polymer layer is formed on the photoresist pattern and the node insulating layer. The polymer layer is etched using the photoresist pattern as an etching mask to expose the node insulating layer while leaving a portion of the polymer layer after etching on a top surface of the exposed node insulating layer and on a sidewall of the opening of the photoresist pattern. The node insulating layer is etched using the photoresist pattern and the polymer layer as an etching mask to form a confined contact hole extending through the node insulating layer to contact the lower electrode layer while forming a polymer layer on a sidewall of the confined contact hole as a byproduct of etching the node insulating layer. The photoresist pattern, the portion of the polymer layer and the polymer layer on the sidewall of the confined contact hole are removed from the semiconductor substrate and a phase-change layer is formed on the node insulating layer to substantially fill the confined contact hole.

In some embodiments of the present invention, etching the node insulating layer using the photoresist pattern and the polymer layer as an etching mask to form a confined contact hole further includes etching the lower electrode layer to form the confined contact hole extending through the node insulating layer and into the lower electrode layer. Etching the polymer layer using the photoresist pattern as an etching mask to expose the node insulating layer while leaving a portion of the polymer layer after etching on a top surface of the exposed node insulating layer and on a sidewall of the opening of the photoresist pattern may include forming an etching byproduct polymer layer on a sidewall of the portion of the polymer layer. Etching the node insulating layer using the photoresist pattern and the polymer layer as an etching mask to form a confined contact hole may include etching the node insulating layer using the photoresist pattern, the polymer layer and the etching byproduct polymer layer as an etching mask to form the confined contact hole. Removing the photoresist pattern may include removing the etching byproduct polymer layer and the method may further include forming an upper electrode layer on the phase-change layer.

In other embodiments of the present invention, the node insulating layer includes an anti-reflection layer on a top surface thereof and the opening in the photoresist pattern exposes the anti-reflection layer. Forming a polymer layer in such embodiments includes forming the polymer layer on the exposed anti-reflection layer and etching the polymer layer includes etching the anti-reflection layer. Etching the node insulating layer includes etching the node insulating layer using the anti-reflection layer as an etching mask and removing the photoresist pattern includes removing the anti-reflection layer from the semiconductor substrate.

In further embodiments of the present invention, forming a lower electrode layer and forming a photoresist pattern include sequentially forming a lower electrode layer, a node insulating layer, and a photoresist pattern exposing the node insulating layer on the semiconductor substrate. Etching the node insulating layer includes successively etching the node insulating layer and the lower electrode layer using the photoresist patterns, the polymer layer, and the first etching byproduct polymer layer as an etching mask, while simultaneously forming the confined contact hole in the lower electrode layer through the node insulating layer and the etching byproduct polymer layer on the sidewall of the portion of the polymer layer. Forming the phase-change layer and the upper electrode includes sequentially forming the phase-change layer and the upper electrode layer on the node insulating layer to sufficiently fill the confined contact hole.

In other embodiments of the present invention, the confined contact hole is formed extending along a horizontal line in a same direction as the active region. In alternative embodiments the confined contact hole is formed extending along a horizontal line in a direction traversing the active region. The confined contact hole may have a width smaller than a width of the active region.

In yet further embodiments of the present invention, the phase-change layer is a compound including chalcogenide, for example, germanium (Ge), antimony (Sb) and tellurium (Te) (GexSbyTez), with added nitrogen (N), selenium (Se), bismuth (Bi), plumbum (Pb), antimony (Sb), arsenic (As), sulfur (S), phosphor (P), nickel (Ni) and/or palladium (Pd).

In other embodioments of the present invention, the methods include, after forming the upper electrode layer, forming a photoresist pattern on a predetermined region of the upper electrode layer aligned with the confined contact hole. The upper electrode layer, the phase-change layer, the node insulating layer and the lower electrode layer are sequentially etched using the photoresist pattern as an etching mask and the photoresist pattern is removed from the semiconductor substrate. Sequentially etching the upper electrode layer, the phase-change layer, the node insulating layer and the lower electrode layer forms a node insulating layer pattern from the node insulating layer and concurrently forms a phase-change layer pattern and an upper electrode on the node insulating layer pattern and a lower electrode under the node insulating layer pattern.

In further embodiments of the present invention, the lower and upper electrode layers are formed of a material that is substantially unaffected by high current densities and that is non-reactive with a material of the phase-change layer. The lower and upper electrode layers may be titanium nitride (TiN), titanium aluminum nitride (TiAIN), tantalum nitride (TaN), titanium tungsten (TiW), tungsten (W), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), tantalum silicide (TaSi), titanium silicide (TiSi), titanium oxynitride (TiON), titanium aluminum oxynitride (TiAlON), tungsten oxynitride (WON), tantalum oxynitride (TaON), and/or copper (Cu). The etching byproduct polymer layers may be formed by reacting an etching process gas containing C_{X}H_{Y}F_{Z}(X≧1, Y≧0, Z≧1) or a mixture thereof with the photoresist pattern.

The etching byproduct polymer layers may be formed by reacting an etching process gas containing CHF₃, CF₄ or a mixture thereof with the photoresist pattern. The etching byproduct polymer layer on a sidewall of the portion of the polymer layer may be formed by adding argon to an etching process gas containing C_{X}H_{Y}F_{Z}(X≧1, Y≧0, Z≧1) or a mixture thereof and reacting the etching process gas containing the argon with the photoresist pattern. The etching byproduct polymer layer on a sidewall of the portion of the polymer layer may be formed by adding argon to an etching process gas containing CHF₃, CF₄ or a mixture thereof and reacting the etching process gas containing the argon with the photoresist pattern. The etching byproduct polymer layer on a sidewall of the portion of the polymer layer may be formed by adding nitrogen (N₂) to an etching process gas containing C_{X}H_{Y}F_{Z}(X≧1, Y≧0, Z≧1) or a mixture thereof and reacting the etching process gas containing the nitrogen with the photoresist pattern. The etching byproduct polymer layer on a sidewall of the portion of the polymer layer may be formed by adding nitrogen (N₂) to an etching process gas containing CHF₃, CF₄ or a mixture thereof and reacting the etching process gas containing the nitrogen with the photoresist pattern.

In other embodiments of the present invention, etching the polymer layer is performed by an etching process having an etching ratio with respect the photoresist pattern and the node insulating layer. Etching the node insulating layer may be performed by an etching process having an etching ratio with respect to the photoresist pattern. Forming the polymer layer may include exposing the photoresist pattern to a plasma having a high molecular deposition condition. The plasma may be an etching process gas including C_{X}H_{Y}F_{Z}(X≧1, Y≧0, Z≧1) . The plasma may be an etching process gas including C₄H₈, C₅F₈, CHF₃ and/or CH₂F₂. The node insulating layer may be a material selected from a group consisting of silicon oxide (SiO₂), silicon oxynitride (SiON) and silicon nitride (Si₃N₄). The anti-reflection layer may be one or more organic and/or inorganic materials that reduce an interference of photo-light.

In yet further embodiments of the present invention, methods of forming a phase-change random access memory (PRAM) include sequentially forming a lower electrode layer, a node insulating layer, an anti-reflection layer, and a photoresist pattern exposing the anti-reflection layer on an active region of a semiconductor substrate, the photoresist pattern being formed to have an opening therein. A polymer layer is formed covering the photoresist pattern and the anti-reflection layer. An etching process is performed on the polymer layer and the anti-reflection layer using the photoresist pattern as an etching mask to expose the node insulating layer, the etching process forming the polymer layer remaining after etching on a sidewall of the opening of the photoresist pattern and on a top surface of the anti-reflection layer, and a first etching byproduct polymer layer covering a sidewall of the polymer layer. An etching process is successively performed on the node insulating layer and the lower electrode layer using the photoresist pattern, the anti-reflection layer, the polymer layer and the first etching byproduct polymer layer as an etching mask, the etching process simultaneously forming a confined contact hole in the lower electrode layer through the node insulating layer and a second etching byproduct polymer layer on a sidewall of the confined contact hole. The photoresist pattern is removed together with the first and second etching byproduct polymer layers, the polymer layer and the anti-reflection layer from the semiconductor substrate. A phase-change layer and a upper electrode layer are sequentially formed on the node insulating layer to sufficiently fill the confined contact hole.

### BRIEF DESCRIPTION OF THE DRAWINGS

FIG. 1 is a plane view illustrating a PRAM according to some embodiments of the present invention.

FIGS. 2 through 13 are cross-sectional views illustrating methods of forming a PRAM taken along line I-I′ of FIG. 1 according to some embodiments of the present invention.

FIG. 14 is a graph illustrating electrical characteristics of PRAMs according to some embodiments of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting or the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

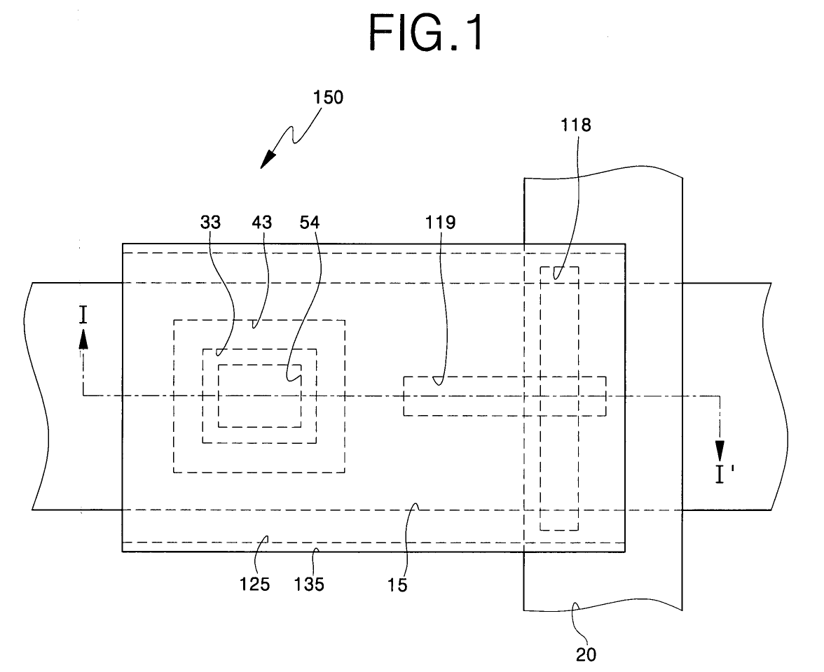

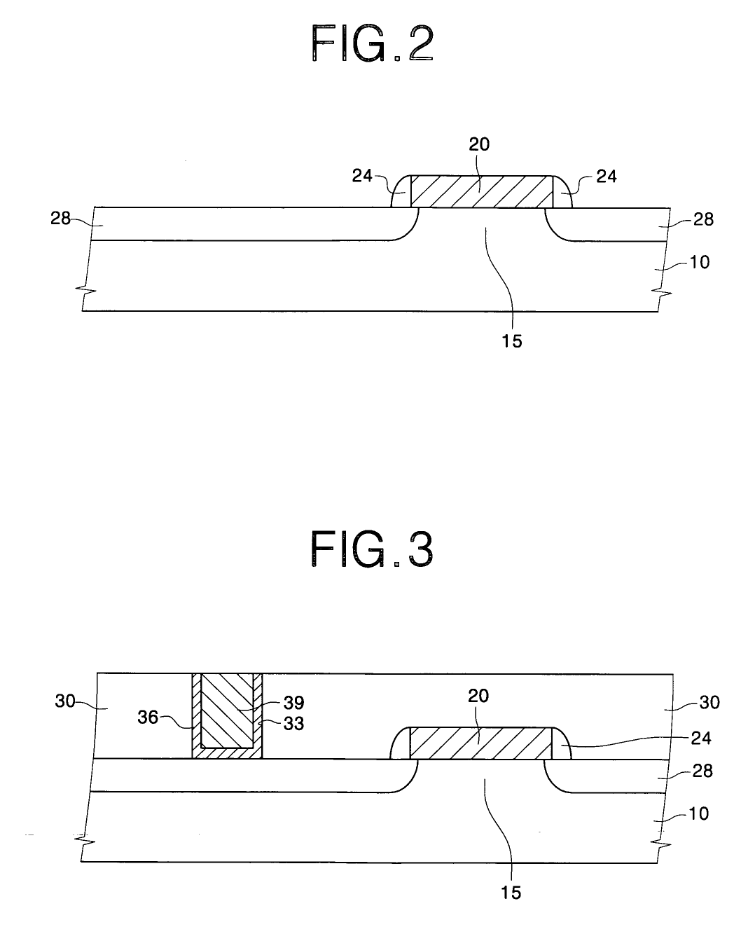

Various embodiments of the present invention will now be described with reference to the figures. FIG. 1 is a plane view illustrating a PRAM according to some embodiments of the present invention. FIGS. 2 to 13 are cross-sectional views taken along line I-I′ of FIG. 1 that illustrate methods of forming a PRAM according to some embodiments of the present invention.

Referring now to the embodiments of FIGS. 1 to 4, a gate pattern 20 is shown formed on an active region 15 of a semiconductor (integrated circuit) substrate 10. For purposes of the description herein the semiconductor substrate 10 will be considered as having P-type impurity ions. The gate pattern 20 may be formed of a sequentially stacked gate and a gate capping layer pattern. The gate capping layer pattern may be formed of a silicon nitride (Si₃N₄). The gate may be formed of an N+ type doped polysilicon. Gate spacers 24 are illustrated as formed on respective sidewalls of the gate pattern 20. The gate spacers 24 may be formed of an insulating layer having the same etching ratio as that of the gate capping layer pattern.

Source/drain regions 28 are illustrated formed in the semiconductor substrate 10, which overlap the gate pattern 20. The source/drain regions 28 may be formed of impurity ions having a conductive type different from that of the semiconductor substrate 10. Thus, for a P-type doped substrate, the source/drain regions 28 may be formed of N-type impurity ions.

A pad interlayer insulating layer 30 is illustrated formed on the semiconductor substrate 10 to sufficiently cover the gate pattern 20. The pad interlayer insulating layer 30 may be formed of an insulating layer material having an etching ratio different from that of the gate spacer 24. The pad interlayer insulating layer 30 may be formed, for example, of silicon oxide (SiO₂).

As illustrated in the embodiments of FIG. 3, a pad contact hole 33 is formed to expose one of the source/drain regions 28. A pad adhesion layer pattern 36 and a pad conductive layer pattern 39 are shown, which fill the pad contact hole 33. The pad adhesion layer pattern 36 and pad conductive layer pattern 39 may be sequentially formed. The pad conductive layer pattern 39 in some embodiments is formed of tungsten (W). The pad adhesion layer pattern 36 in some embodiments is formed of titanium nitride (TiN).

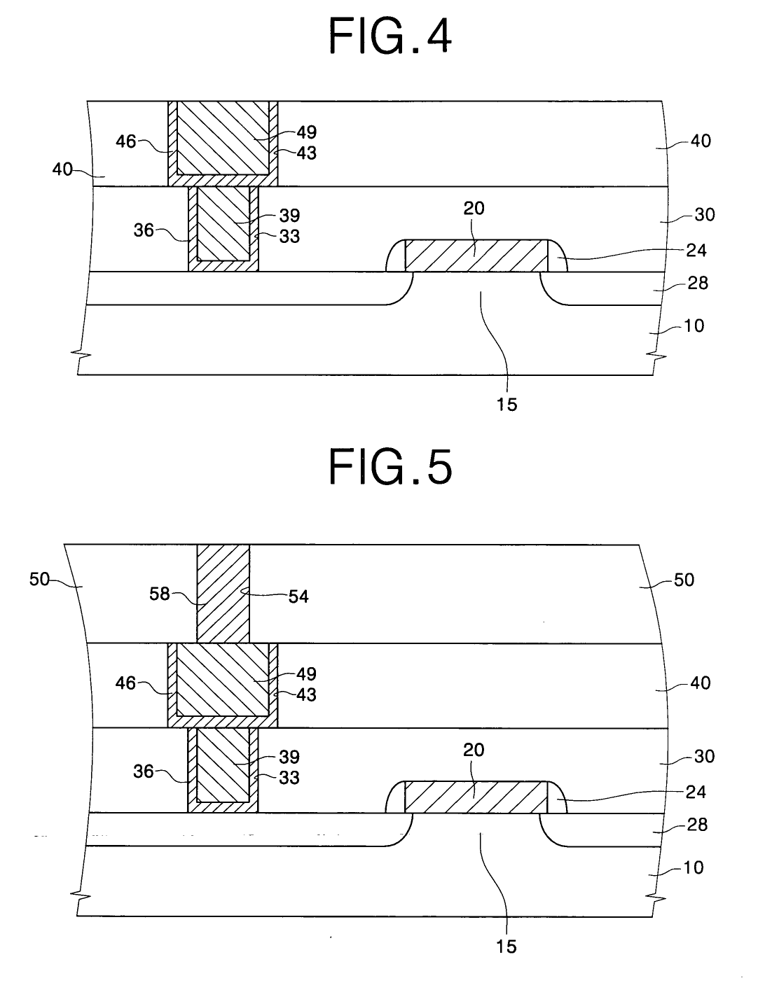

As seen in the embodiments of FIG. 4, a buried interlayer insulating layer 40 is formed on the pad interlayer insulating layer 30 to cover the pad adhesion layer pattern 36 and the pad conductive layer pattern 39. The buried interlayer insulating layer 40 in some embodiments is formed of an insulating layer material having a substantially same etching ratio as the pad interlayer insulating layer 30.

For the embodiments of FIG. 4, a buried contact hole 43 is formed above the pad contact hole 33 to penetrate the buried interlayer insulating layer 40. The buried contact hole 43 is formed to expose the pad adhesion layer pattern 36 and the pad conductive layer pattern 39. A buried adhesion layer pattern 46 and a buried conductive layer pattern 49, which may fill the buried contact hole 43, may then be sequentially formed. The buried conductive layer pattern 49 in some embodiments is formed of tungsten (W). The buried adhesion layer pattern 46 may be formed of titanium nitride (TiN).

Referring now to the embodiments illustrated in FIG. 1 and FIGS. 5 through 8, a planarization interlayer insulating layer 50 is formed on the buried interlayer insulating layer 40 to cover the buried adhesion layer pattern 46 and the buried conductive layer pattern 49. The planarization interlayer insulating layer 50 may be formed of an insulating layer material having the same etching ratio as that of the buried interlayer insulating layer 40. A node contact hole 54 is shown formed above the buried contact hole 43 to penetrate the planarization interlayer insulating layer 50. The node contact hole 54 exposes the buried conductive layer pattern 49. As seen in FIGS. 5-8, a node conductive layer pattern 58 is formed in and may fill the node contact hole 54. The node conductive layer pattern 58 may be formed of TiN.

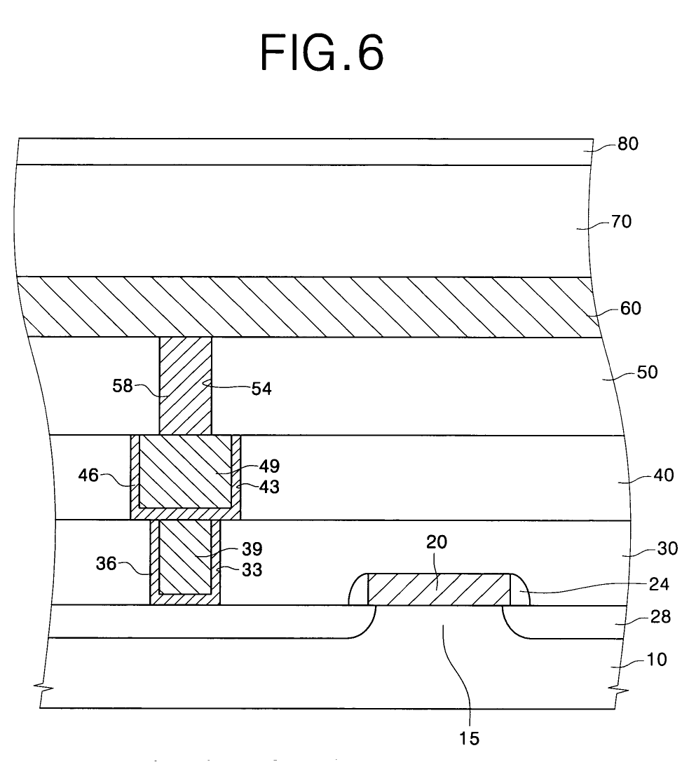

As seen in the embodiments of FIG. 6, a lower electrode layer 60, a node insulating layer 70 and an anti-reflection layer (ARL) 80 are sequentially formed on the planarization interlayer insulating layer 50 to cover the node conductive layer pattern 58. In other embodiments of the present invention, the ARL 80 may be omitted and the lower electrode layer 60 and the node insulating layer 70 may be sequentially formed on the planarization interlayer insulating layer 50 to cover the node conductive layer pattern 58. The ARL 80 may be formed of one or more materials selected from an organic material and an inorganic material that reduce an interference of photo-light during a photolithography process. The node insulating layer 70 may be formed of an insulating layer material having an etching ratio different from that of the planarization interlayer insulating layer 50. The node insulating layer 70 in some embodiments is formed of a material selected from a group consisting of silicon oxide (SiO₂), silicon oxynitride (SiON) and silicon nitride (Si₃N₄). The lower electrode layer 60 may be formed of the same conductive layer material as that of the node conductive layer pattern 58. The lower electrode layer 60 may be formed of a material layer including titanium nitride (TiN), titanium aluminum nitride (TiAlN), tantalum nitride (TaN), titanium tungsten (TiW) , tungsten (W), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), tantalum silicide (TaSi), titanium silicide (TiSi), titanium oxyitride (TiON), titanium aluminum oxynitride (TiAlON), tungsten oxynitride (WON), tantalum oxynitride (TaON), copper (Cu) and/or the like that has a relatively high immunity to a high current density.

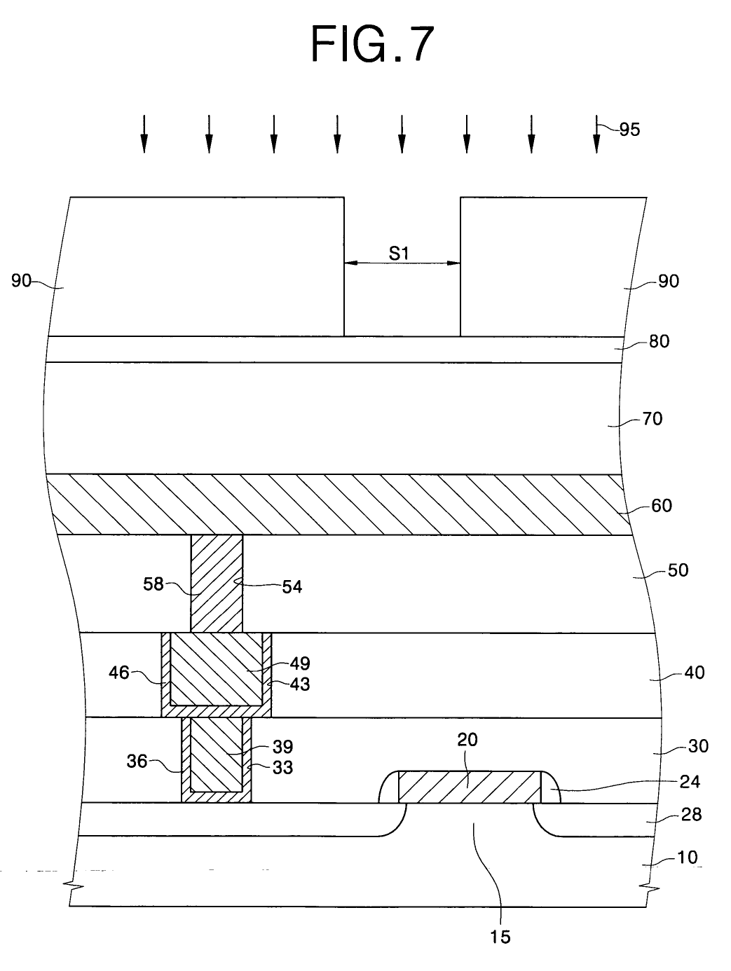

Referring next to the embodiments of FIG. 7, a photoresist pattern 90 is formed to expose the ARL 80. The photoresist pattern 90 has an opening therein that, for the embodiments of FIG. 7, has a predetermined diameter S1. An etching process 95 is performed on the photoresist pattern 90 and the ARL 80. The etching process 95 may be performed to have an etching ratio with respect to the ARL 80 by using an etching process gas containing CF₄, O₂ and/or the like.

The etching process 95 can be performed to partially etch the ARL 80 through the opening of the photoresist pattern 90 without exposing the node insulating layer 70 in other embodiments, the etching process 95 may expose the node insulating layer 70, for example, by using a photoresist pattern 90 deposited on a structure not including the ARL 80.

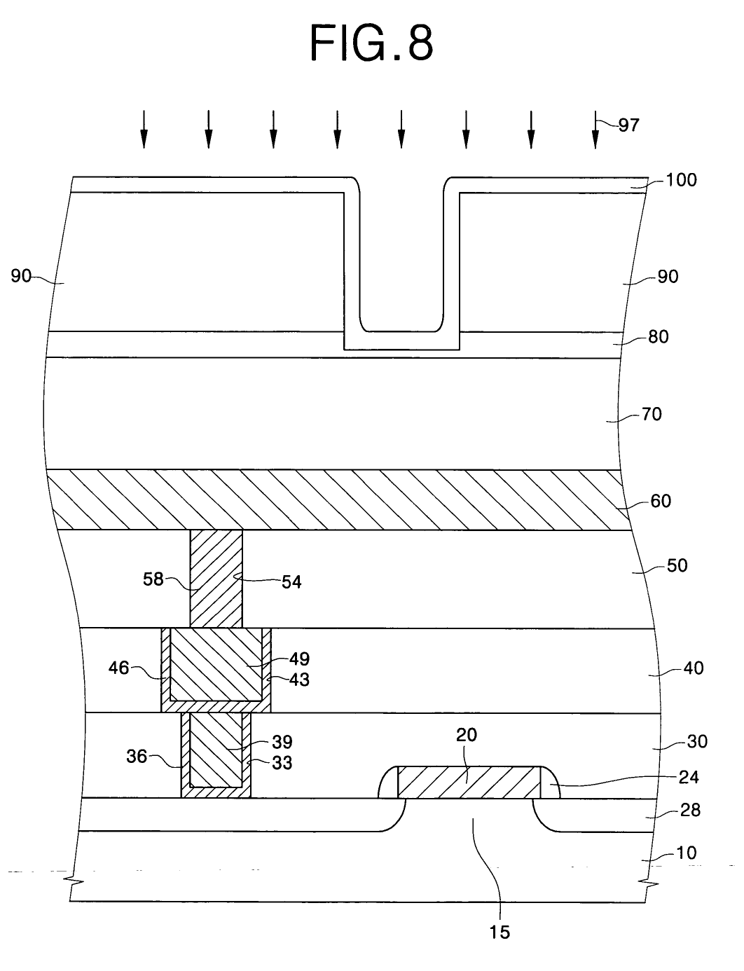

As schematically illustrated in FIG. 8, an etching process 97 is performed on the photoresist pattern 90 and the ARL 80. The illustrated etching process 97 forms a polymer layer 100 covering the photoresist pattern 90 and the ARL 80. The polymer layer 100 may be formed by exposing the photoresist pattern 90 and the ARL 80 to a plasma having a high molecular deposition condition within a process chamber of an etching apparatus. The plasma having the high molecular deposition condition may be formed by using a process gas containing C_{X}H_{Y}F_{Z}(X≧1, Y≧0, Z≧1) and/or the like in which a carbon to fluorine ratio is relatively high compared, for example to the exemplary etching process gases described for the etching process 95. That is, the plasma having the high molecular deposition condition may be formed by using a process gas containing C₄H₈, C₅F₈, CHF₃, CH₂F₂ and/or the like in which a carbon to fluorine ratio is relatively high compared, for example to the exemplary etching process gases described for the etching process 95.

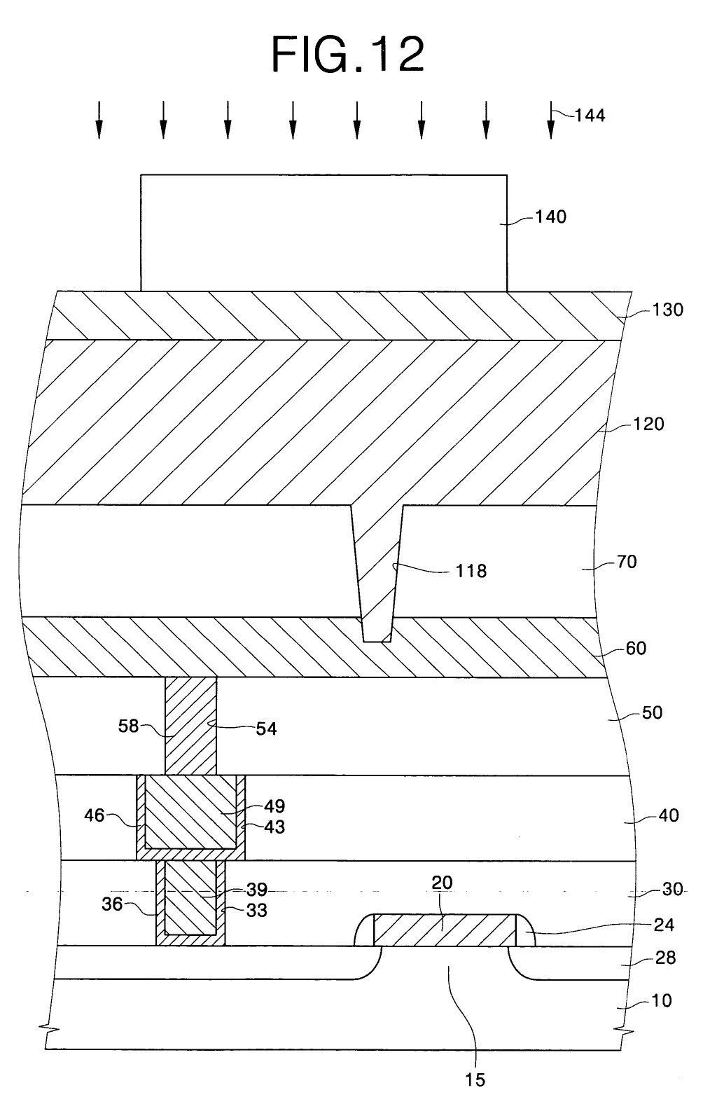

In other embodiments, the etching process 97 may be performed to form a polymer layer 100 covering the photoresist pattern 90 and the node insulating layer 70 in structures (ex. FIG. 12) not including the ARL 80. The etching process 97 in such embodiments may still be performed to have an etching ratio with respect to the photoresist pattern 90 and the node insulating layer 70. The polymer layer 100 may still be formed by exposing the photoresist pattern 90 to a plasma having a high molecular deposition condition within a process chamber, for example, of an etching apparatus. The plasma having the high molecular deposition condition may be formed using an etching process gas containing C_{X}H_{Y}F_{Z}(X≧1, Y≧0, Z≧1) and/or the like in which a carbon to fluorine ratio is relatively high. The etching process 97 may be performed such that the node insulating layer 70 is not partially removed through the opening of the photoresist pattern 90. That is, the plasma having the high molecular deposition condition may be formed using an etching process gas containing C₄H₈, C₅F₈, CHF₃, CH₂F₂ and/or the like in which a carbon to fluorine ratio is relatively high. The etching process 97 may be performed such that the node insulating layer 70 is not partially removed through the opening of the photoresist pattern 90.

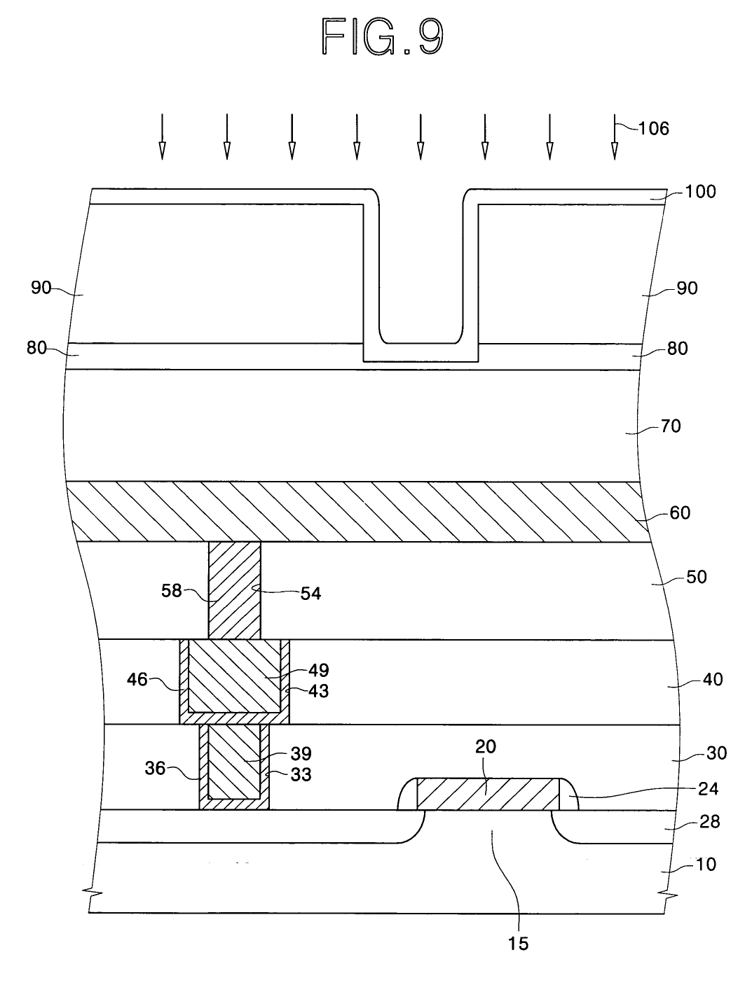

Referring now to the embodiments of FIG. 1, and FIGS. 9-11, an etching process 106 is performed on the polymer layer 100 and the ARL 80, to expose the node insulating layer 70, using the photoresist pattern 90 as an etching mask. The etching process 106 in some embodiments is performed to have an etching ratio with respect to the photoresist pattern 90 and the node insulating layer 70. Based on etching characteristics, the etching process 106 may optimize/maximize an etching amount of the photoresist pattern 90 and the polymer layer 100 at a position where top and side surfaces of the photoresist pattern 90 meet. Accordingly, the etching process 106 may be performed to form a remaining polymer layer 100, remaining on a sidewall of the opening of the photoresist pattern 90 and on a top surface of the ARL 80 after etching, and a first etching byproduct polymer layer 103 covering a sidewall of the polymer layer 100.

In other embodiments, the etching process 106 may be performed on the polymer layer 100, using the photoresist pattern 90 as an etching mask, to expose the node insulating layer 70 where there is no underlying ARL 80. The etching process 106 may be performed to have an etching ratio with respect the photoresist pattern 90 and the node insulating layer 70 and, in view of etching characteristics, the etching process 106 may optimize/maximize an etching amount of the photoresist pattern 90 and the polymer layer 100 at the position where the top and the side surfaces of the photoresist pattern 90 meet. As such, the etching process 106 may still operate to form a remaining polymer layer 100 after etching on the sidewall of the opening of the photoresist pattern 90 and on a top surface of the node insulating layer 70, and the first etching byproduct polymer layer 103 covering the sidewall of the polymer layer 100.

The etching process 106 may react the photoresist pattern 90 with an etching process gas containing C_{X}H_{Y}F_{Z}(X≧1, Y≧0, Z≧1) or a mixture thereof in which a carbon to fluorine ratio is relatively high to form the first etching byproduct polymer layer 103. That is, the etching process 106 may react the photoresist pattern 90 with an etching process gas containing CHF₃, CF₄ or a mixture thereof in which a carbon to fluorine ratio is relatively high to form the first etching byproduct polymer layer 103. The etching process 106 may add argon (Ar) or nitrogen (N₂) to the etching process gas containing C_{X}H_{Y}F_{Z}(X≧1, Y≧0, Z≧1) and/or a mixture thereof in which the carbon to fluorine ratio is high, and may concurrently react the etching process gas containing the argon or nitrogen with the photoresist pattern 90 to form the first etching byproduct polymer layer 103. That is, the etching process 106 may add argon (Ar) or nitrogen (N₂) to the etching process gas containing CHF₃, CF₄ and/or a mixture thereof in which the carbon to fluorine ratio is high, and may concurrently react the etching process gas containing the argon or nitrogen with the photoresist pattern 90 to form the first etching byproduct polymer layer 103. Thus, the etching process 106 may use the polymer layer 100 and the first etching byproduct polymer layer 103 to reduce the diameter S1 of the opening of the photoresist pattern 90 to a predetermined diameter S2.

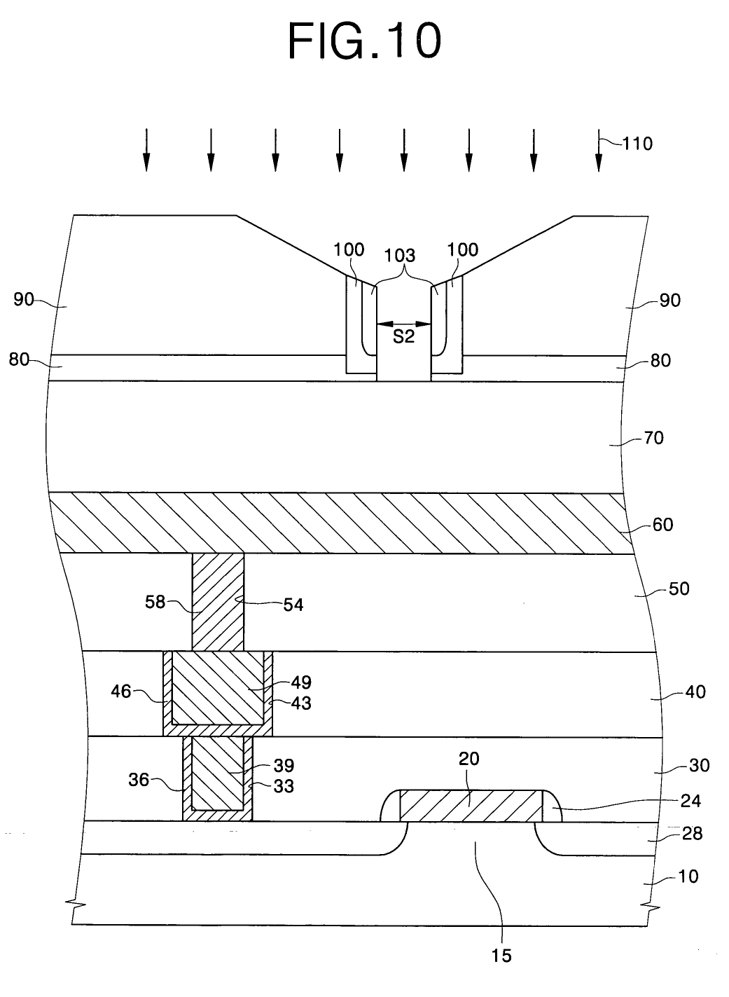

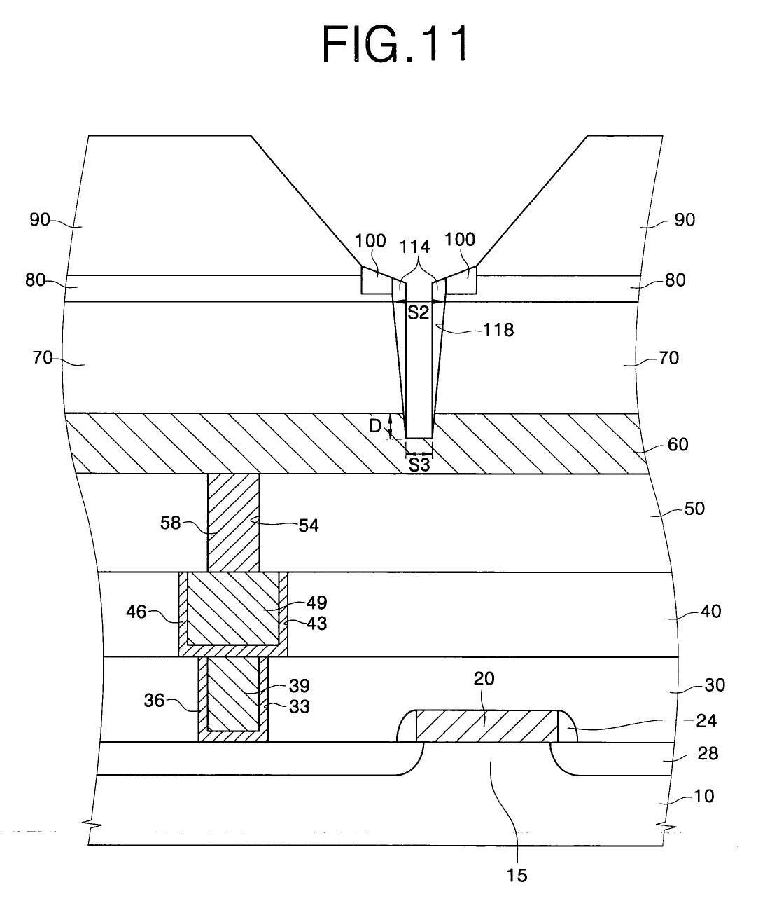

An etching process 110 may then be continuously performed on the node insulating layer 70 and the lower electrode layer 60 using the photoresist patterns 90, the ARL 80, the polymer layer 100 and the first etching byproduct polymer layer 103 as an etching mask. In other embodiments, the etching process 110 may be continuously performed on the node insulating layer 70 and the lower electrode layer 60 by using the photoresist patterns 90, the polymer layer 100 and the first etching byproduct polymer layer 103 as an etching mask without inclusion of the ARL 80. Again, the etching process 110 may be performed to have an etching ratio with respect the photoresist patterns 90. The etching process 110 may optimize/maximize an amount of etching of the photoresist pattern 90 and the polymer layer 100 at a position where the top surface and an inclined surface of the photoresist pattern 90 meet. Accordingly, an upper diameter of the opening of the photoresist pattern 90 may become larger than that illustrated in the embodiments of FIG. 10. As seen in FIG. 11, the etching process 110 may be performed through the node insulating layer 70 to form not only a confined contact hole 118 to the lower electrode layer 60 but also a second etching byproduct polymer layer 114 on a sidewall of the confined contact hole 118.

The etching process 110 may react the photoresist pattern 90 and the node insulating layer 70 with an etching process gas containing C_{X}H_{Y}F_{Z}(X≧1, Y≧0, Z≧1) and/or a mixture thereof in which a carbon to fluorine ratio is relatively high to form the second etching byproduct polymer layer 114. That is, the etching process 110 may react the photoresist pattern 90 and the node insulating layer 70 with an etching process gas containing CHF₃, CF₄ and/or a mixture thereof in which a carbon to fluorine ratio is relatively high to form the second etching byproduct polymer layer 114. The etching process 110 may add argon or nitrogen (N₂) to the etching process gas containing C_{X}H_{Y}F_{Z}(X≧1, Y≧0, Z≧1) and/or a mixture thereof in which the carbon to fluorine ratio is high, and may concurrently react the etching process gas containing the argon or nitrogen with the photoresist pattern 90 and the node insulating layer 70 to form the second etching byproduct polymer layer 114. That is, the etching process 110 may add argon or nitrogen (N₂) to the etching process gas containing CHF₃, CF₄ and/or a mixture thereof in which the carbon to fluorine ratio is high, and may concurrently react the etching process gas containing the argon or nitrogen with the photoresist pattern 90 and the node insulating layer 70 to form the second etching byproduct polymer layer 114. The etching process 110 may allow sizes of an upper diameter S2 and a lower diameter S3 of the confined contact hole 118 to be different from each other by means of the second etching byproduct polymer layer 114.

In some embodiments the confined contact hole 118 is extended by a predetermined depth D downward below a lower surface of the node insulating layer 70 (i.e., into the lower electrode layer 60), using the etching process 110, to effectively expose the lower electrode layer 60. The confined contact hole 118 may be formed to have a diameter smaller than the diameter S1 of the opening in the photoresist pattern 90 shown in FIG. 7. The confined contact hole 118 in some embodiments is disposed on at least one horizontal line in a direction traversing the active region 15 (see FIG. 1) and has a width smaller or larger than a width of the active region 15. In addition, the confined contact hole 118 may have a width smaller or larger than the width of the active region 15. The confined contact hole 118 may, in some embodiments, be formed as a confined contact hole 119 (see FIG. 1) on at least one horizontal line in a same direction as the direction in which the active region 15 runs. Also note that, as is clear from consideration of FIG. 1, while references S1, S2 and S3 are referred to herein as diameters that term shall be understood to encompass a designation of a width of a non-circular region, such as the extending confined contact hole 118, 119.

Referring now to the embodiments of FIG. 1 and FIGS. 12-13, after the etching process 110 is performed, the first and second etching byproduct polymer layers 103 and 114, the polymer layer 100, the ARL 80 and the photoresist pattern 90 are removed from the semiconductor substrate 10 using, for example, an ashing process. In other embodiments not including the ARL 80 (FIG. 12), after the etching process 110 is performed, the first and second etching byproduct polymer layers 103 and 114, the polymer layer 100 and the photoresist pattern 90 may be removed from the semiconductor substrate 10. A radio frequency (RF) cleaning process may subsequently be performed on the confined contact hole 118 using the node insulating layer 70 as an etching mask. The RF cleaning process may remove contaminants that may be present on the lower electrode layer 60. The RF cleaning process may be performed using inactive gas plasma, such as argon and/or the like.

As seen in the embodiments of FIG. 12, a phase-change layer 120 and an upper electrode layer 130 covering he phase-change layer 120 are formed on the node insulating layer 70, which effectively fill the confined contact hole 118. As a result, a predetermined region of the phase-change layer 120 is confined in the node insulating layer 70. The upper electrode layer 130) as well as the lower electrode layer 60, may be formed of a material layer including titanium nitride (TiN), titanium aluminum nitride (TiAlN), tantalum nitride (TaN), titanium tungsten (TiW), tungsten (W), tungsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), tantalum silicide (TaSi), titanium silicide (TiSi), titanium oxynitride (TiON), titanium aluminum oxynitride (TiAlON), tungsten oxynitride (WON), tantalum oxynitride (TaON), copper (Cu) and/or the like that has immunity to a high current density and does not substantially react with the phase-change layer 120. The phase-change layer 120 may be a mixture (GeₓSb_{y}Te_{z}), referred to as Chalcogenide, containing germanium, antimony and tellurium, which may be formed including nitrogen (N), selenium (Se), bismuth (Bi), plumbum (Pb), antimony(Sb), arsenic (As), sulfur (S), phosphor (P), nickel (Ni), palladium (Pd) and/or the like that are added thereto.

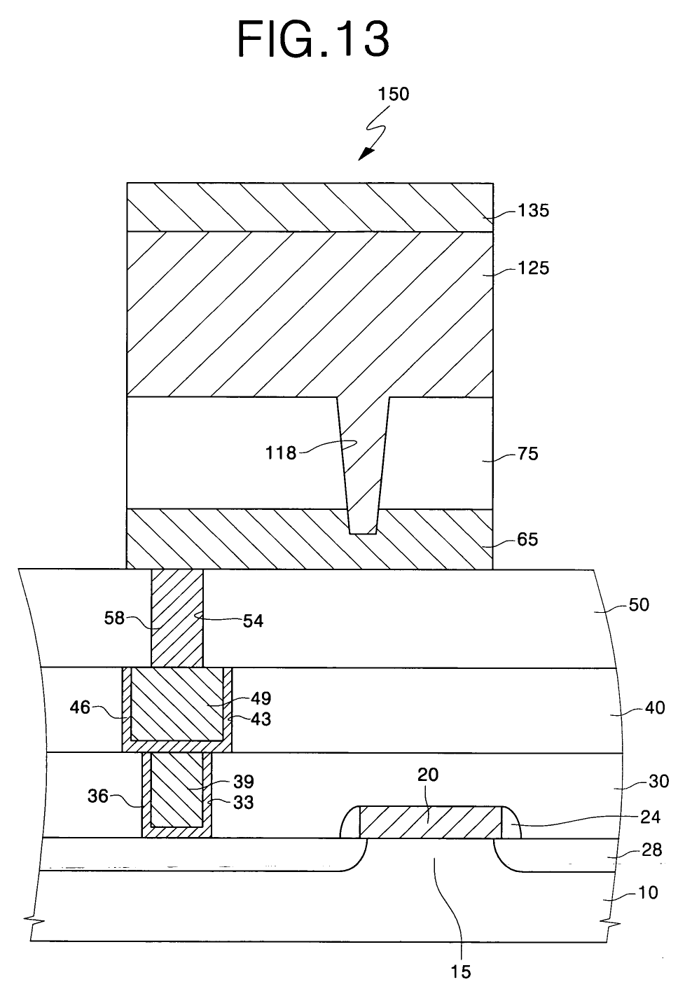

A photoresist pattern 140 is shown formed disposed in a predetennined region on the upper electrode layer 130 and aligned with the confined contact hole 118. An etching process 144 may then be sequentially performed on the upper electrode layer 130, the phase-change layer 120, the node insulating layer 70 and the lower electrode layer 60 using the photoresist pattern 140 as an etching mask. As seen in FIG. 13, the etching process 144 may use the node insulating layer 70 to form a node insulating layer pattern 75 while also forming a phase-change layer pattern 125 and a upper electrode 135 on the node insulating layer pattern 75 as well as a lower electrode 65 below the node insulating layer pattern 75. The photoresist pattern 140 may then be removed from the semiconductor substrate 10 to form a PRAM 150 according to some embodiments of the present invention.

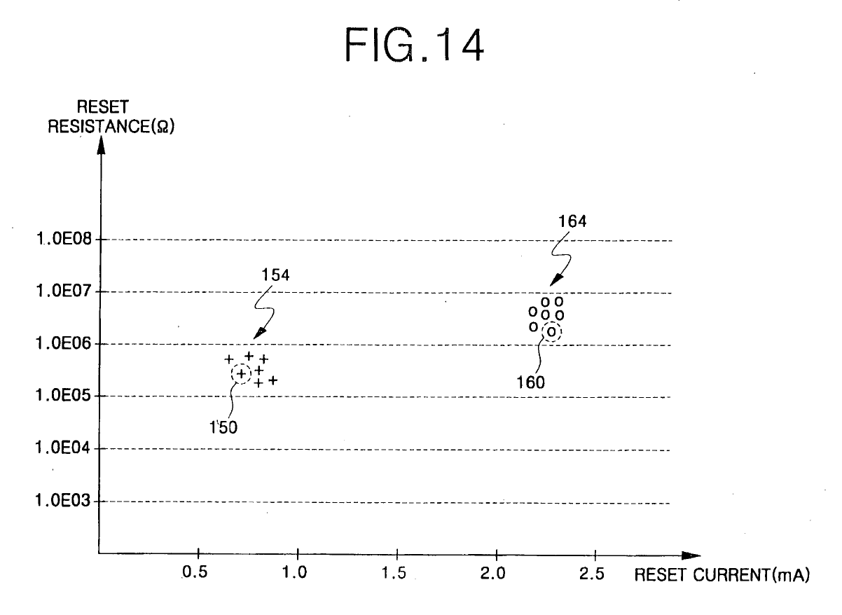

FIG. 14 is a graph illustrating electrical characteristics of PRAMs according some embodiments of the present invention. Referring to FIGS. 13 and 14, a plurality of PRAMs 150 and 160 are prepared in order to compare magnitudes of operable reset current from a design point of view. The PRAMs 150 and 160 may be classified into a first group 154 and a second group 164. The first group 154 represents PRAMs 150 according to some embodiments of the present invention as illustrated, for example, in FIG. 13. The second group 164 represents PPAMs 160 in which the phase-change layer pattern 125 directly contacts the node conductive layer pattern 58 of FIG. 12 without having the lower electrode 65. Accordingly, the operable reset current from the design point of view is typically dependent on the size of the lower diameter S3 (more particularly, a contact surface area dependent on the dimension S3) of the confined contact hole 118 in the first group 154, and is dependent on the diameter (more particularly, a contact surface area dependent on the diameter, which term again encompasses a width of a corresponding area as seen with reference to FIG. 1) of the node contact hole 54 in the second group 164. The diameter of the confined contact hole 118 may provide a smaller contact area than that of the node contact hole 54.

When the electrical characteristics of the two groups 154 and 164 are compared, it can be seen that the PRAMs 150 according to some embodiments of the present invention may allow “0” data, that is operable from the design point of view, to be stably stored in a selected cell, although a low reset current is consumed compared to the PRAMs 160.

As discussed above, some embodiments of the present invention provide methods of forming a PRAM having a phase-change layer pattern confined in a node insulating layer pattern by forming a confined contact hole in the node insulating layer pattern and a lower electrode. The methods may operate acceptably even with the gradual shrinkage of the design rule of PRAM and allow the operable reset current of PRAM to be continuously decreased along with the design rule, which may be beneficial in satisfying needs of the semiconductor market.

Some embodiments of the invention provide methods of forming a PRAM having a phase-change layer pattern confined in a node insulating layer pattern. According to some embodiments of the invention, methods of forming a PRAM include sequentially forming a lower electrode layer, a node insulating layer, an anti-reflection layer, and a photoresist pattern exposing the anti-reflection layer on a semiconductor substrate of an active region. The photoresist pattern is formed to have an opening therein. A polymer layer covers the photoresist pattern and the anti-reflection layer. An etching process is performed on the polymer layer and the anti-reflection layer, using the photoresist pattern as an etching mask, to expose the node insulating layer. The etching process forms the polymer layer remaining after etching on a sidewall of the opening of the photoresist pattern and on a top surface of the anti-reflection layer, and a first etching byproduct polymer layer covering a sidewall of the polymer layer. An etching process is successively performed on the node insulating layer and the lower electrode layer by using the photoresist pattern, the anti-reflection layer, the polymer layer and the first etching byproduct polymer layer as an etching mask. The etching process simultaneously forms a confined contact hole in the lower electrode layer through the node insulating layer and a second etching byproduct polymer layer on a sidewall of the confined contact hole. The photoresist pattern is removed together with the first and second etching byproduct polymer layers, the polymer layer and the anti-reflection layer from the semiconductor substrate. A phase-change layer and a upper electrode layer are sequentially formed on the node insulating layer to sufficiently fill the confined contact hole.

According to the other embodiments of the invention, methods of forming a PRAM include sequentially forming a lower electrode layer, a node insulating layer, and a photoresist pattern exposing the node insulating layer on a semiconductor substrate of an active region. The photoresist pattern is formed to have an opening therein. A polymer layer covers the photoresist pattern and the node insulating layer. An etching process is performed on the polymer layer by using the photoresist pattern as an etching mask to expose the node insulating layer. The etching process forms the polymer layer remaining after etching on a top surface of the node insulating layer and on a sidewall of the opening of the photoresist pattern, and a first etching byproduct polymer layer covering a sidewall of the polymer layer. An etching process is successively performed on the node insulating layer and the lower electrode layer by using the photoresist patterns, the polymer layer, and the first etching byproduct polymer layer as an etching mask. The etching process simultaneously forms a confined contact hole in the lower electrode layer through the node insulating layer and a second etching byproduct polymer layer on a sidewall of the confined contact hole. The photoresist patterns are removed together with the first and second etching byproduct polymer layers and the polymer layer from the semiconductor substrate. A phase-change layer and an upper electrode layer are sequentially formed on the node insulating layer to sufficiently fill the confined contact hole.

The foregoing is illustrative of the present invention and is not to be constnied as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein

What is claimed is:

1. A method of forming a phase-change random access memory (PRAM), comprising:
forming a lower electrode layer and a node insulating layer on an active region of a semiconductor substrate;
forming a photoresist pattern on the node insulating layer including an opening therein;
forming a polymer layer on the photoresist pattern and the node insulating layer;
etching the polymer layer using the photoresist pattern as an etching mask to expose the node insulating layer while leaving a portion of the polymer layer after etching on a top surface of the exposed node insulating layer and on a sidewall of the opening of the photoresist pattern;
etching the node insulating layer using the photoresist pattern and the polymer layer as an etching mask to form a confined contact hole extending through the node insulating layer to contact the lower electrode layer while forming a polymer layer on a sidewall of the confined contact hole as a byproduct of etching the node insulating layer;
removing the photoresist pattern, the portion of the polymer layer and the polymer layer on the sidewall of the confined contact hole from the semiconductor substrate; and
forming a phase-change layer on the node insulating layer to substantially fill the confined contact hole.

2. The method of claim 1 wherein etching the node insulating layer using the photoresist pattern and the polymer layer as an etching mask to form a confined contact hole further comprises etching the lower electrode layer to form the confined contact hole extending through the node insulating layer and into the lower electrode layer.

3. The method of claim 2 wherein etching the polymer layer using the photoresist pattern as an etching mask to expose the node insulating layer while leaving a portion of the polymer layer after etching on a top surface of the exposed node insulating layer and on a sidewall of the opening of the photoresist pattern further comprises forming an etching byproduct polymer layer on a sidewall of the portion of the polymer layer and wherein etching the node insulating layer using the photoresist pattern and the polymer layer as an etching mask to form a confined contact hole comprises etching the node insulating layer using the photoresist pattern, the polymer layer and the etching byproduct polymer layer as an etching mask to form the confined contact hole.

4. The method of claim 3 wherein removing the photoresist pattern further includes removing the etching byproduct polymer layer and wherein the method further comprises forming an upper electrode layer on the phase-change layer.

5. The method of claim 4 wherein the node insulating layer includes an anti-reflection layer on a top surface thereof and wherein the opening in the photoresist pattern exposes the anti-reflection layer and wherein fonling a polymer layer includes forming the polymer layer on the exposed anti-reflection layer and wherein etching the polymer layer includes etching the anti-reflection layer and wherein etching the node insulating layer includes etching the node insulating layer using the anti-reflection layer as an etching mask and wherein removing the photoresist pattern includes removing the anti-reflection layer from the semiconductor substrate.

6. The method of claim 4 wherein:
forming a lower electrode layer and forming a photoresist pattern comprise sequentially forming a lower electrode layer, a node insulating layer, and a photoresist pattern exposing the node insulating layer on the semiconductor substrate;
etching the node insulating layer comprises successively etching the node insulating layer and the lower electrode layer using the photoresist patterns, the polymer layer, and the etching byproduct polymer layer as an etching mask, while simultaneously forming the confined contact hole in the lower electrode layer through the node insulating layer and the etching byproduct polymer layer on the sidewall of the portion of the polymer layer; and
forming the phase-change layer and the upper electrode comprises sequentially forming the phase-change layer and the upper electrode layer on the node insulating layer to sufficiently fill the confined contact hole.

7. The method of claim 4 wherein the confined contact hole is formed extending along a horizontal line in a same direction as the active region.

8. The method of claim 7 wherein the confined contact hole has a width smaller than a width of the active region.

9. The method of claim 4 wherein the confined contact hole is formed extending along a horizontal line in a direction traversing the active region.

10. The method of claim 9 wherein the confined contact hole has a width smaller than a width of the active region.

11. The method of claim 4 wherein the phase-change layer comprises a chalcogenide compound including genmanium (Ge), antimony (Sb) and tellurium (Te) (GexSbyTez), with added nitrogen (N), selenium (Se), bismuth (Bi), plumbum (Pb), antimony (Sb), arsenic (As), sulfur (S), phosphor (P), nickel (Ni) and/or palladium (Pd).

12. The method of claim 4, further comprising:
after forming the upper electrode layer, forming a photoresist pattern on a predetermined region of the upper electrode layer aligned with the confined contact hole;
sequentially etching the upper electrode layer, the phase-change layer, the node insulating layer and the lower electrode layer using the photoresist pattern as an etching mask; and
removing the photoresist pattern from the semiconductor substrate;
wherein sequentially etching the upper electrode layer, the phase-change layer, the node insulating layer and the lower electrode layer forms a node insulating layer pattern from the node insulating layer and concurrently forms a phase-change layer pattern and an upper electrode on the node insulating layer pattern and a lower electrode under the node insulating layer pattern.

13. The method of claim 12 wherein the lower and upper electrode layers are formed of a material that is substantially unaffected by high current densities and which is non-reactive with a material of the phase-change layer.

14. The method of claim 13 wherein the lower and upper electrode layers comprise titanium nitride (TiN), titanium aluminum nitride (TiAlN), tantalum nitride (TaN), titanium tungsten (TiW), tungsten (W), tlingsten nitride (WN), molybdenum nitride (MoN), niobium nitride (NbN), titanium silicon nitride (TiSiN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium (Ti), molybdenum (Mo), tantalum (Ta), tantalum silicide (TaSi), titanium silicide (TiSi), titanium oxynitride (TiON), titanium aluminum oxynitride (TiAlON), tungsten oxynitride (WON), tantalum oxynitride (TaON), and/or copper (Cu).

15. The method of claim 4 wherein the etching byproduct polymer layers are formed by reacting an etching process gas containing C_{X}H_{Y}F_{Z}(X≧1, Y≧0, Z≧1) or a mixture thereof with the photoresist pattern.

16. The method of claim 4 wherein the etching byproduct polymer layers are formed by reacting an etching process gas containing CHF₃, CF₄ or a mixture thereof with the photoresist pattern.

17. The method of claim 4 wherein the etching byproduct polymer layer on a sidewall of the portion of the polymer layer is formed by adding argon to an etching process gas containing C_{X}H_{Y}F_{Z}(X≧1, Y≧0, Z≧1) or a mixture thereof and reacting the etching process gas containing the argon with the photoresist pattern.

18. The method of claim 4 wherein the etching byproduct polymer layer on a sidewall of the portion of the polymer layer is formed by adding argon to an etching process gas containing CHF₃, CF₄ or a mixture thereof and reacting the etching process gas containing the argon with the photoresist pattern.

19. The method of claim 4 wherein the etching byproduct polymer layer on a sidewall of the portion of the polymer layer is formed by adding nitrogen (N₂) to an etching process gas containing C_{X}H_{Y}F_{Z}(X≧1, Y≧0, Z≧1) or a mixture thereof and reacting the etching process gas containing the nitrogen with the photoresist pattern.

20. The method of claim 4 wherein the etching byproduct polymer layer on a sidewall of the portion of the polymer layer is formed by adding nitrogen (N₂) to an etching process gas containing CHF₃, CF₄ or a mixture thereof and reacting the etching process gas containing the nitrogen with the photoresist pattern.

21. The method of claim 4 wherein etching the polymer layer is performed by an etching process having an etching ratio with respect to the photoresist pattern and the node insulating layer.

22. The method of claim 4 wherein etching the node insulating layer is performed by an etching process having an etching ratio with respect to the photoresist pattern.

23. The method of claim 4 wherein forming the polymer layer includes exposing the photoresist pattern to a plasma having a high molecular deposition condition.

24. The method of claim 23 wherein the plasma comprises an etching process gas including C_{X}H_{Y}F_{Y}(X≧1, Y≧0, Z≧1).

25. The method of claim 23 wherein the plasma comprises an etching process gas including C₄H₈, C₅F₈, CHF₃ and/or CH₂F₂.

26. The method of claim 4 wherein the node insulating layer comprises a material selected from a group consisting of silicon oxide (SiO₂), silicon oxynitride (SiON) and silicon nitride (Si₃N₄).

27. The method of claim 5 wherein the anti-reflection layer comprises one or more organic and/or inorganic materials that reduce an interference of photo-light.

28. A method of forming a phase-change random access memory (PRAM), comprising:
sequentially forming a lower electrode layer, a node insulating layer, an anti-reflection layer, and a photoresist pattern exposing the anti-reflection layer on an active region of a semiconductor substrate, the photoresist pattern being formed to have an opening therein;
forming a polymer layer covering the photoresist pattern and the anti-reflection layer;
performing an etching process on the polymer layer and the anti-reflection layer using the photoresist pattern as an etching mask to expose the node insulating layer, the etching process forming the polymer layer remaining after etching on a sidewall of the opening of the photoresist pattern and on a top surface of the anti-reflection layer, and a first etching byproduct polymer layer covering a sidewall of the polymer layer;
successively performing an etching process on the node insulating layer and the lower electrode layer using the photoresist pattern, the anti-refection layer, the polymer layer and the first etching byproduct polymer layer as an etching mask, the etching process simultaneously forming a confined contact hole in the lower electrode layer through the node insulating layer and a second etching byproduct polymer layer on a sidewall of the confined contact hole;
removing the photoresist pattern together with the first and second etching byproduct polymer layers, the polymer layer and the anti-reflection layer from the semiconductor substrate; and
sequentially forming a phase-change layer and a upper electrode layer on the node insulating layer to sufficiently fill the confined contact hole.
